(19) United States
(12) Patent Application Publication
(10) Pub. No.: US 2006/0225162 A1
(43) Pub. Date: Oct. 5, 2006

(54) Method of making a substrate structure with enhanced surface area

(76) Inventor: Sungsoo Yi, Sunnyvale, CA (US)

Correspondence Address: AGILENT TECHNOLOGIES INC.;INTELLECTUAL PROPERTY ADMINISTRATION, LEGAL DEPT,, M/S DU404, P.O. BOX 7599, LOVELAND, CO, 80537-0599, US

(21) Appl. No.: 11/095,634

(22) Filed: Mar. 30, 2005

(51) Int. Cl. H01L 21/4763

(52) U.S. Cl. 977/754; 977/894; 438/618

(57) ABSTRACT

A substrate having a surface is provided; first nanoparticles are deposited on the surface of the substrate; first nanowires are grown extending from the first nanoparticles to the surface of the substrate; second nanoparticles are deposited on the first nanowires; and second nanowires are grown extending from the second nanoparticles to the first nanowires to form branched nanostructures. Each nanowire growth process provides a geometric increase in the surface area of the substrate structure. Additional nanoparticles may be subsequently deposited and additional nanowires may be grown from the additional nanoparticles to provide a further increase in the surface area of the substrate structure.

### BACKGROUND

In certain applications, for example, spectroscopic applications such as surface plasmon resonance and surface-enhanced Raman scattering, target molecules are captured by a surface. The sensitivity of such applications depends on the concentration of the target molecules captured by the surface: a high concentration of captured target molecules increases the level of the detection signal obtainable. It is known that the concentration of target molecules that can be captured can be increased by capturing the target molecules using a substrate having an enhanced surface area, i.e., a substrate whose surface area is greater than its geometrical area. In the case of a rectangular substrate, the geometrical area is the product of the length and the width of the substrate. Although any surface area greater than the geometrical area is helpful, a surface area that is at least one order of magnitude greater than the geometrical area is desirable.

The surface area of a substrate is typically increased relative to the geometrical area thereof by contouring or otherwise forming a three-dimensional structure at the substrate surface. However, conventional contouring methods produce a relatively modest increase in surface area.

What is needed, therefore, is a method of making a substrate structure having a surface area one or more orders of magnitude larger than the geometrical area of the substrate.

### SUMMARY

In a first aspect, the invention provides a method of making a substrate structure having an enhanced surface area. The method comprises providing a substrate having a surface; depositing first nanoparticles on the surface of the substrate; growing first nanowires extending from the first nanoparticles to the surface of the substrate; depositing second nanoparticles on the first nanowires; and growing second nanowires extending from the second nanoparticles to the first nanowires to form branched nanostructures.

Each nanowire growth process increases the surface area of the substrate structure. Additional nanoparticles may be subsequently deposited and additional nanowires may be grown from the additional nanoparticles to provide a further increase in the surface area of the substrate structure.

An embodiment of the method provides a substrate structure incorporating an electromagnetic field enhancing layer. In this, a thin layer of an electromagnetic field enhancing metal, such as silver, gold or copper, is deposited on the nanowires as the electromagnetic field enhancing layer.

In a second aspect, the invention provides a substrate structure having an enhanced surface area. The substrate structure comprises a substrate and branched nanostructures extending from the surface of the substrate. At least some of the branched nanostructures have at least two levels of branching.

In a third aspect, the invention provides a method of making a substrate structure having an enhanced surface area. The method comprises providing a substrate having a substrate surface; depositing nanoparticles on the substrate surface; growing nanowires extending from the nanoparticles; and repeating the depositing and the growing until branched nanostructures formed by the growing have a predetermined level of branching, the depositing comprising additionally depositing nanoparticles on the nanowires.

### BRIEF DESCRIPTION OF THE DRAWINGS

FIG. 1 is a flow chart illustrating a first embodiment of a method in accordance with the invention for making a substrate structure having an enhanced surface area.

FIGS. 2A-2E illustrate the fabrication of a substrate structure by the process shown in FIG. 1.

FIG. 2F is a side view of an exemplary embodiment of a substrate structure in accordance with the invention.

FIGS. 3A-3F illustrate an exemplary process for growing nanowires.

FIG. 4 is a phase diagram showing how the melting point of an exemplary alloy of silicon and gold varies with the silicon fraction in the alloy.

FIG. 5 is a flow chart illustrating a second embodiment of a method in accordance with the invention for making a substrate structure having an enhanced surface area.

FIG. 6 is a flow chart illustrating a third embodiment of a method in accordance with the invention for making a substrate structure having an enhanced surface area.

FIG. 7 illustrates an exemplary process for depositing nanoparticles by electron beam evaporation.

### DETAILED DESCRIPTION

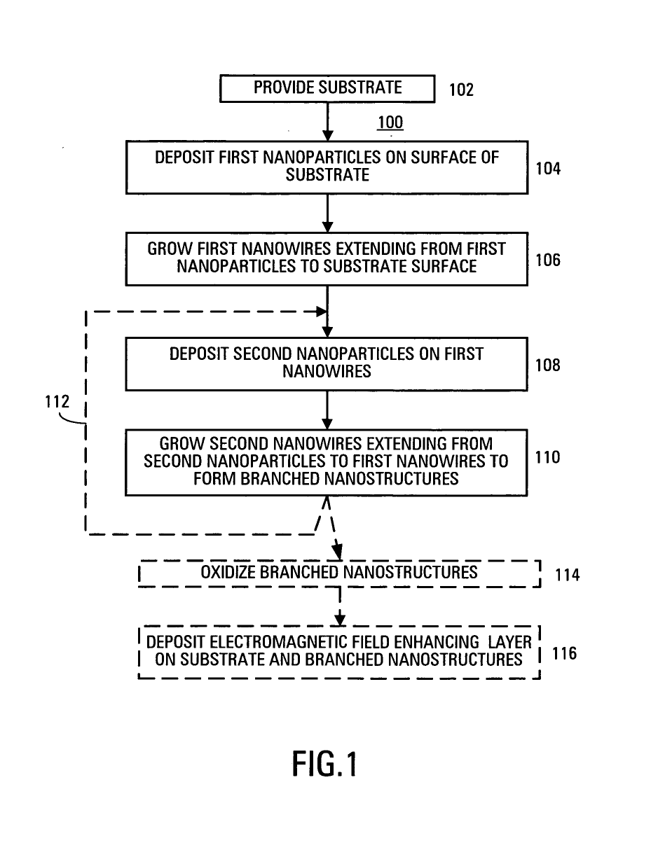

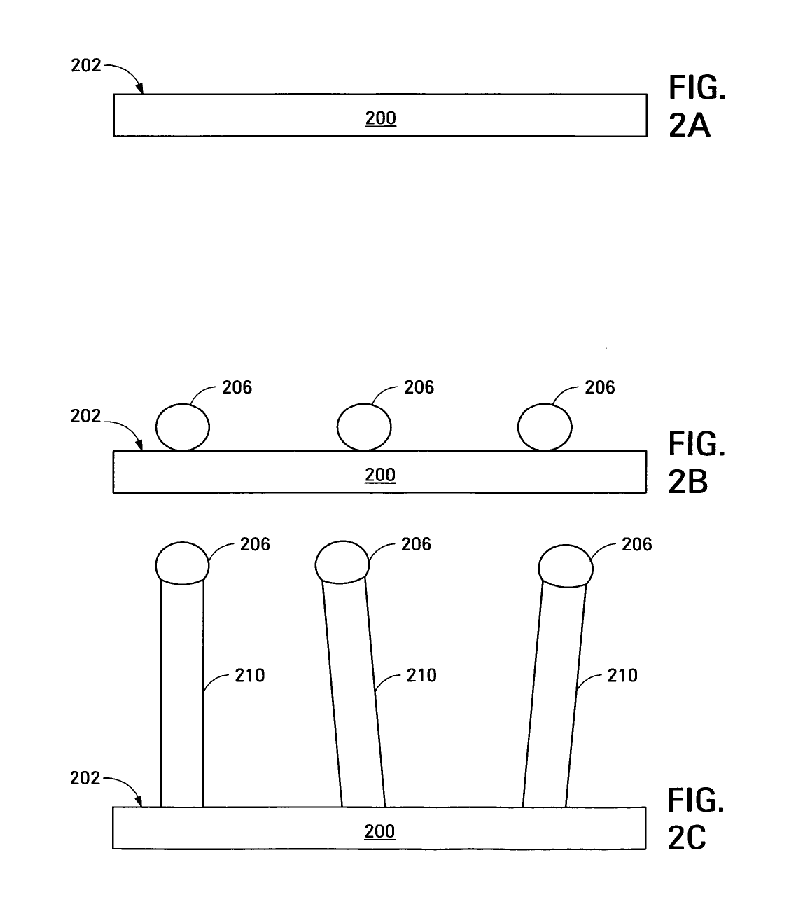

FIG. 1 is a flow chart illustrating a first embodiment 100 of a method in accordance with the invention for making a substrate structure having an enhanced surface area. Method 100 will be described with additional reference to FIGS. 2A-2F, which show use of an example of the method.

In block 102, a substrate is provided. FIG. 2A shows an exemplary small region of a substrate 200. Substrate 200 has a surface indicated at 202.

In block 104, first nanoparticles are deposited on the surface of the substrate. FIG. 2B shows first nanoparticles 206 deposited on surface 202.

In block 106, first nanowires are grown extending from the first nanoparticles to the surface of the substrate. FIG. 2C shows first nanowires 210 that have been grown extending from first nanoparticles 206 to surface 202.

In block 108, second nanoparticles are deposited on the first nanowires. FIG. 2D shows second nanoparticles 212 deposited on first nanowires 210. The deposition process also deposits additional second nanoparticles, shown at 222, on surface 202.

In block 110, second nanowires are grown extending from the second nanoparticles to the first nanowires. FIG. 2E shows second nanowires 214 grown from the second nanoparticles 212 deposited on first nanowires 210 and extending to first nanowires 210, and additionally shows second nanowires 224 grown from the second nanoparticles 222 deposited the surface 202 of substrate 200 and extending to surface 202. Each of the first nanowires 210 and the second nanowires 214 extending therefrom collectively constitute a branched nanostructure 234.

The branching of branched nanostructures 234 is characterized by a level of branching. The level of branching of a branched nanostructure is the number of nanowire-to-nanowire junctions that exist along a path that extends between the distal end of the most recently grown nanowires (second nanowires 214 in the example shown in FIG. 2E) and the substrate. The branched nanowires 234 shown in FIG. 234 have a single level of branching because no more than one nanowire-to-nanowire junction (i.e., the junction between second nanowire 214 and first nanowire 210) exists along a path that extends from the distal end of the most recently grown nanowire, i.e., second nanowire 214, through first nanowire 210 to substrate 200.

Branched nanostructures 234, substrate 200 and second nanowires 224 that extend to the surface 202 of substrate 200 collectively constitute a substrate structure 230. The surface area of substrate structure 230 is the sum of the geometrical area of substrate 200 and the surface areas of all the nanostructures 234 and second nanowires 224, and is typically at least one order of magnitude greater than the geometrical surface area of substrate 200.

FIG. 1 also shows optional loop 112 that extends from after block 110 to before block 108. In embodiments in which loop 112 is performed one or more times, in block 108, additional nanoparticles are deposited on surface 202 and on the surfaces of the nanowires grown in the earlier nanowire growth processes, such as nanowire growth processes 106 and 110. Then, in block 110, additional nanowires are grown extending from such additional nanoparticles.

FIG. 2F shows an example of substrate structure 230 made by an embodiment of process 100 in which loop 112 has been performed once. In FIG. 2F, not all of the additional nanoparticles and additional nanowires are labelled to simplify the drawing. In the example shown in FIG. 2F, additional nanowires 254 grown from additional nanoparticles 252 deposited on second nanowires 214, 224 extend to second nanowires 214, 224; additional nanowires 264 grown from additional nanoparticles 262 deposited on first nanowires 210 extend to first nanowires 210; and additional nanowires 274 grown from additional nanoparticles 272 deposited the surface 202 of substrate 200 extend to surface 202.

In the example shown in FIG. 2F, each branched nanostructure 234 is composed of at least two of the following three elements: a first nanowire 210, a second nanowire 214, 224, and an additional nanowire 254, 264. In general, branched nanostructures 234 each have up to n+1 levels of branching, where n is the number of times the loop 112 has been performed. In the example shown in FIG. 2F, each branched nanostructure 234 has up to two levels of branching, since loop 112 has been performed once. For example, one of the branched nanostructures 234, i.e., branched nanostructure 236, comprises first nanowire 210, second nanowire 214 extending from first nanowire 210, and additional nanowire 254 extending from second nanowire 214 and therefore has two nanowire-to-nanowire junctions (one between nanowire 254 and nanowire 214 and one between nanowire 214 and nanowire 210) between the distal end of nanowire 254 and substrate 200. Hence, branched nanostructure 236 has two levels of branching. On the other hand, another of the branched nanostructures 234, branched nanostructure 238, comprises second nanowire 224 extending from substrate 200 and additional nanowire 254 extending from second nanowire 224 and therefore has only one nanowire-to-nanowire junction (that between nanowire 254 and nanowire 224). Hence, branched nanostructure 238 has only one level of branching. Thus, branched nanostructures 234 have up to two levels of branching.

The surface area of substrate structure 230 is the sum of the geometrical area of substrate 200 and the surface areas of all the nanostructures 234, and of nanowires 224 and 274, and is typically at least one order of magnitude greater than the geometrical surface area of substrate 200.

FIG. 1 additionally shows optional blocks 114 and 116 that singly or together additionally form part of some embodiments of method 100.

Some applications need an embodiment of substrate structure 230 in which the semiconductor material of branched nanostructures 234 is converted to an oxide. Such embodiment is made by additionally performing optional block 114. In block 114, branched nanostructures 234 are oxidized.

In surface-enhanced optical spectroscopy applications such as surface plasmon resonance and surface-enhanced Raman scattering and other applications, a thin layer of an electromagnetic field enhancing metal such as Ag, Au and Cu is conventionally deposited on the surface of the substrate. The metal layer deposited on nanoscale structures enhances the electromagnetic field of the incoming light at the metal surface, and can therefore be regarded as an electromagnetic field enhancing layer. A layer having a thickness equal to or less than the largest cross-sectional dimension of the largest nanowires will be regarded as thin. Substrate structure 230 can similarly incorporate an electromagnetic field enhancing layer. An embodiment of substrate structure 230 incorporating an electromagnetic field enhancing layer is made by additionally performing optional block 116 shown in FIG. 1. In block 116, a thin layer of an electromagnetic field enhancing metal is deposited on branched nanostructures 234 as the electromagnetic field enhancing layer. The electromagnetic field enhancing metal is typically silver, gold or copper. The electromagnetic field enhancing layer is typically deposited by evaporation, sputtering or another suitable deposition method.

Some applications incorporate an embodiment of substrate structure 230 in which an electromagnetic field enhancing layer is supported by a nanoscale substructure. Such an embodiment is made by additionally performing optional blocks 114 and 116 shown in FIG. 1. In block 114, branched nanostructures 234 are oxidized to make them suitable for subsequent surface modification. Then, in block 116, a layer of an electromagnetic field enhancing metal is deposited on the branched nanostructures to provide the electromagnetic field enhancing layer.

A practical example of method 100 will now be described with reference to FIG. 2A-2F. The portion of substrate 200 shown in FIG. 2A is a portion of a silicon wafer on which hundreds or thousands of substrate structures similar to substrate structure 230 are fabricated simultaneously by the same processes. The wafer is divided into individual substrates by a conventional singulation process after growth of nanostructures 234 has been completed.

Alternatively, substrate 200 may be a portion of a silica (SiO₂) wafer. As an additional alternative, surface 202 may be the surface of a silicon dioxide layer formed by oxidizing the surface of a silicon wafer or by depositing a layer of silicon dioxide on a silicon wafer by chemical vapor deposition. Suitable oxidation and deposition processes are well known in the semiconductor arts. Other useable substrate materials include glass, quartz, gallium arsenide (GaAs) and indium phosphide (InP). Both GaAs and InP are available in form of wafers of single-crystal material. However, silicon, glass or quartz can be used as the substrate material in embodiments in which the material of the nanostructures is gallium arsenide or indium phosphide and are substantially less expensive.

The first nanoparticles 206 deposited as shown in FIG. 2B are metal nanoparticles. In the example shown, nanoparticles of colloidal gold (Au) were deposited as the first nanoparticles. The first nanoparticles typically have an average size in the range from about 50 nm to about 200 nm and are supplied as an aqueous colloidal solution. In an exemplary embodiment, the average size of the first nanoparticles was about 100 nm. Alternative materials for the first nanoparticles are nickel (Ni), titanium (Ti) and gallium (Ga). Liquids other than water may be used as the liquid component of the colloidal solution.

First nanoparticles 206 are deposited on the surface 202 of substrate 200 as follows. The wafer of which substrate 200 forms part is dipped into the colloidal solution containing the first nanoparticles and is then removed. Excess liquid is then gently removed from the wafer and the wafer is then allowed to dry.

First nanowires 210 are grown as shown in FIG. 2C by any suitable nanowire growth process. In the example shown, a vapor, liquid solid (VLS) process is used. In this, substrate 200 is heated to a temperature close to the melting point of the material of nanoparticles 206 and a precursor gas comprising the constituent element or elements of the material of first nanowires 210 is passed over the surface 202 of substrate 200. A first nanowire 210 then grows from each first nanoparticle 206 extending to the surface 202 of substrate 200. During the growth process, the first nanoparticle remains at the distal end of the first nanowire, i.e., at the end of the first nanowire remote from the substrate. The size of the first nanoparticle determines the cross-sectional dimensions of the first nanowire, i.e., the dimensions in a plane orthogonal to the direction of growth of the first nanowire.

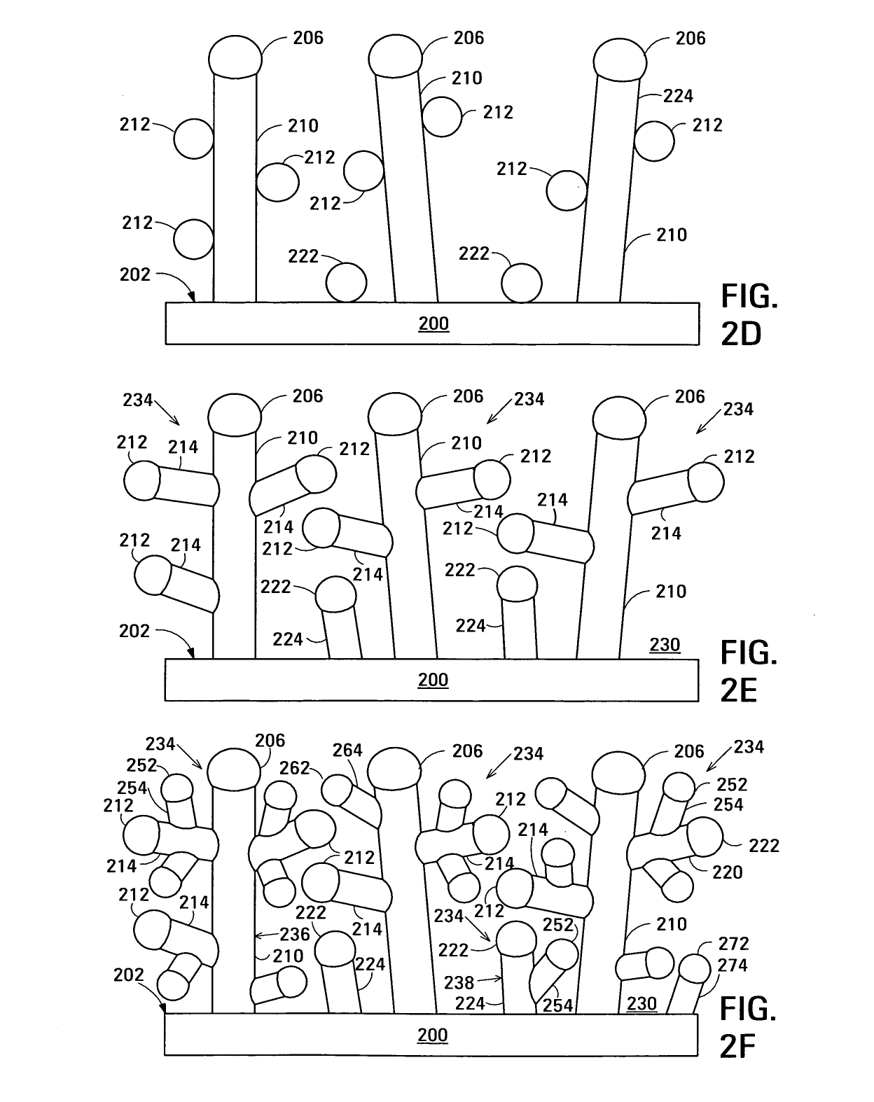

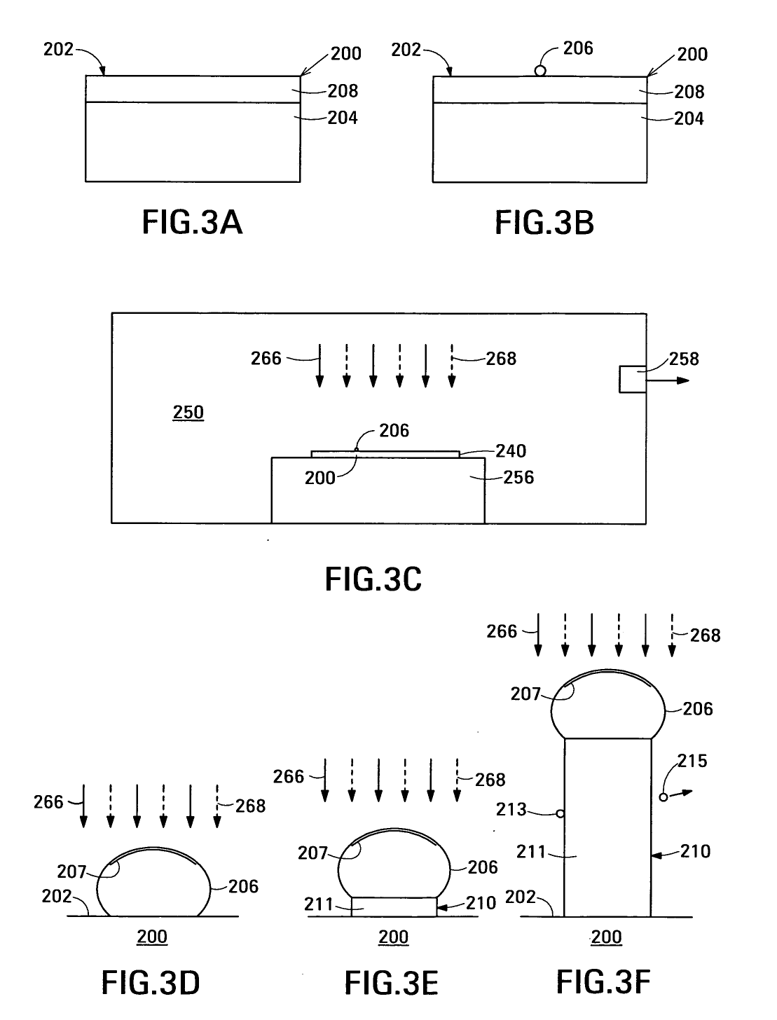

An exemplary VLS growth process suitable for growing first nanowires 210, second nanowires 214, 224 shown in FIG. 2E and, optionally, additional nanowires 254, 264 and 274 shown in FIG. 2F, will be described in detail below with reference to FIGS. 3A-3F and 4.

In an example, first nanowires 210 with a diameter of 40 nm and a length of 1 μm were grown with a density of 10¹⁰ cm² on a substrate having a geometrical area of 1 cm². The resulting substrate structure had a surface area of 12 cm², i.e., twelve times the geometrical area.

The second nanoparticles 212, 222 deposited as shown in FIG. 2D are metal nanoparticles. In the example shown, nanoparticles of colloidal gold (Au) were deposited as the second nanoparticles. The second nanoparticles typically have an average size in the range from about 10 nm to about 30 nm less than that of first nanoparticles 206. In an exemplary embodiment, the average size of the second nanoparticles was about 20 nm less than that of the first nanoparticles. This results in second nanowires 214, 224 being smaller in cross-sectional dimensions than first nanowires 210. Alternatively, second nanoparticles 212, 222 equal in average size to first nanoparticles 206 will result in second nanowires 214, 224 and first nanowires 210 being approximately equal in cross-sectional dimensions.

Alternative materials for second nanoparticles 212, 222 are similar to those of first nanoparticles 206. The second nanoparticles are provided in the form of a colloidal solution as described above with reference to first nanoparticles 206.

Second nanoparticles 212, 222 are deposited by dipping the wafer of which substrate 200 forms part into a colloidal solution containing the second nanoparticles, removing the wafer from the colloidal solution, gently removing excess liquid and allowing the wafer to dry.

The deposition process just described deposits the second nanoparticles on both substrate 200 and first nanowires 210. However, since the collective surface area of first nanowires 210 is greater than that of substrate 200 (11 times in the example described above), the number of second nanoparticles 212, 222 deposited in block 108 of FIG. 1 is significantly greater than the number of first nanoparticles 206 deposited in block 104 of FIG. 1, assuming that the per-unit-area deposition rate of the second nanoparticles does not differ greatly between substrate 200 and first nanowires 210.

Second nanowires 214 are grown as shown in FIG. 2E by any suitable nanowire growth process. In the example shown, a vapor, liquid, solid (VLS) process is used, as will be described in detail below.

The second nanowires 214 grown from second nanoparticles 212 deposited on first nanowires 210 extend to first nanowires 210. The remaining second nanowires 224 grown from second nanoparticles 222 deposited on the surface 202 of substrate 200 extend to surface 202. During the process of growing the second nanowires, the second nanoparticles 212, 222 remain located at the distal ends of the second nanowires 214, 224, respectively. Additionally, although not shown in FIG. 2E, first nanowires 210 grow additionally during the process of growing the second nanowires due to the presence of the first nanoparticles 206 at the distal ends of first nanowires 210. In embodiments in which etch selectivity exists between the materials of first nanoparticles 206 and first nanowires 210, additional growth of the first nanowires during growth of the second nanowires can be prevented by performing an etch process to remove the first nanoparticles from the distal ends of the first nanowires. The etch process is performed after the first nanowires have been grown and before the second nanoparticles are deposited, i.e., between blocks 106 and 108 in FIG. 1. Alternatively, additional growth of the first nanowires during growth of the second nanowires can be prevented by oxidizing the nanoparticles at the end of the first nanowires. After the first nanowires have been grown, the substrate structure is subject to an oxygen plasma treatment that renders first nanoparticles 206 at the ends of first nanowires 210 incapable of catalyzing further growth of the first nanowires. Similar techniques can be used to prevent growth of previously-grown nanowires during subsequently-performed nanowire growth processes.

Growing the second nanowires 214, 224 as just described forms the embodiment of substrate structure 230 shown in FIG. 2E. Substrate structure 230 is composed of substrate 200 and branched nanostructures 234 extending from substrate 200. Each branched nanostructure 234 is composed of a first nanowire 210 and one or more second nanowires 214. Each second nanowire extends laterally from the first nanowire part-way along the length of the first nanowire. Growing the second nanowires further increases the surface area of substrate structure 230.

In an example, first nanowires 210 with a diameter of 40 nm and a length of 1 μm were grown with a density of 10¹⁰ cm⁻² on a substrate having a geometrical area of 1 cm². The resulting substrate structure had a surface area of 12 cm², i.e., twelve times the geometrical area. Second nanoparticles 212 were then deposited with a density of about five per first nanowire and second nanowires 214 were grown with a diameter of 20 nm and a length of 100 nm. This increased the surface area of substrate structure 230 to about 15 times the geometrical area of substrate 200.

FIG. 2F shows another embodiment of substrate structure 230 in accordance with the invention. As mentioned above, the more complex branched nanostructures shown in FIG. 2F are made simply by performing loop 112 shown in FIG. 1 once. In loop 112, the nanoparticle deposition process 106, described above with reference to FIG. 2D, and the nanowire growth process 110, described above with reference to FIG. 2E, are repeated. Performing loop 112 further increases the surface area of substrate structure 230.

Branched nanostructures 234 even more complex than those illustrated in FIG. 2F can be made by performing loop 112 more than once. Each time loop 112 is performed, the surface area of the substrate structure 230 increases further. However, a law of diminishing returns applies as a result of the nanowires grown in each successive performance of loop 112 being progressively shorter and, typically, thinner.

Using nanoparticles of the same average size in nanoparticle deposition processes 104, 108 will result in nanowires of the same cross-sectional dimensions being grown in nanowire growth processes 106, 110, and branched nanostructures 234 in which all the branches have substantially the same cross-sectional dimensions. Alternatively, using nanoparticles with progressively smaller average sizes in the subsequent nanoparticle deposition processes will result in nanowires of progressively smaller cross-sectional dimensions being grown in the nanowire growth processes. This will produce branched nanostructures 234 in which the branches have progressively smaller cross-sectional dimensions. Alternatively, nanoparticles of the same average size can be deposited in some consecutive depositions and nanoparticles of progressively smaller average sizes can be deposited in other consecutive depositions.

In an embodiment of method 100 in which optional block 114 shown in FIG. 1 is performed, the substrate structure fabricated by performing blocks 102, 104, 106, 108 and 110 and, optionally, loop 112 is subject to an oxygen plasma treatment to oxidize branched nanostructures 234.

In an embodiment of method 100 in which block 116 shown in FIG. 1 is performed, the substrate structure fabricated by performing blocks 102, 104, 106, 108 and 110 and, optionally, loop 112 is placed in a vacuum chamber, and a thin layer of an electromagnetic field enhancing metal is deposited on the surfaces of nanowires 210, 214, 224, 254, 264 and 274 to provide the electromagnetic field enhancing layer. The deposition process additionally deposits the electromagnetic field enhancing metal on the surface 202 of substrate 200. The electromagnetic field enhancing metal is typically silver, gold or copper and is deposited by evaporation, sputtering or another suitable process. Alternatively, the processing just described with reference to block 116 may be performed after the processing described above with reference to block 114 has been performed.

An example of a VLS-based nanowire growth process that can be used in block 106 of FIG. 1 to grow first nanowires 210 and in block 110 of FIG. 1 to grow second nanowires 214, 224 will now be described with reference to FIGS. 3A-3F and 4. Use of the process to grow a single nanowire will be described to simplify the explanation.

FIG. 3A is a side view of substrate 200 on which the nanowire will be grown. In the example shown, substrate 200 is composed of a layer 204 of single-crystal silicon having a layer 208 of silicon dioxide on its major surface. Examples of other suitable materials for layer 204 are single-crystal gallium arsenide (GaAs) and single-crystal indium phosphide (InP). However, silicon, glass or quartz can be used as the material of layer 204 in embodiments in which the material of the nanostructures is gallium arsenide or indium phosphide and are substantially less expensive.

In an embodiment, layer 208 is a layer of native oxide formed by heating silicon layer 204 to a high temperature in an oxidizing atmosphere. Alternatively, layer 208 is deposited on the major surface of silicon layer 204 by a deposition process such as plasma-enhanced chemical vapor deposition (PECVD). Substrate 200 is typically a portion of a silicon wafer that is later singulated into hundreds or thousands of substrates similar to substrate 200.

FIG. 3B is a side view of substrate 200 showing an exemplary first nanoparticle 206 of a catalyst material deposited on the major surface 202 of the substrate. A single first nanoparticle is shown to simplify the drawing. First nanoparticle 206 is a nanoparticle of a catalytic material capable of catalytically decomposing a gaseous precursor to release the constituent element of the semiconductor material of which the first nanowires will be grown. In an embodiment, first nanoparticle 206 is a nanoparticle of colloidal gold. Examples of other suitable catalytic materials are nickel (Ni), titanium (Ti) and gallium (Ga). The size of first nanoparticle 206 determines the diameter of the first nanowire. In an embodiment, first nanoparticle 206 had an average size in the range from about 50 nm to about 200 nm.

FIG. 3C is a schematic side view of a CVD reactor 250 showing wafer 240 of which substrate 200 forms part mounted on the susceptor 256 of the reactor. Susceptor 256 and, hence, substrate 200 and nanoparticle 206, are heated to a growth temperature near the eutectic point of an alloy between the material of the nanoparticle and the material of the nanowire. In an embodiment in which the material of nanoparticle 206 was gold, first nanoparticle 206 was heated to a growth temperature of about 450° C.

A growth pressure is established inside reactor 250 and a gaseous precursor mixture is passed over substrate 200. The gaseous precursor mixture is represented by solid arrows, an exemplary one of which is shown at 266, and will be referred to as gaseous precursor mixture 266. Gaseous precursor mixture 266 is composed of a substantially inert carrier gas and one or more precursors in a gaseous state. In an embodiment in which the semiconductor material of the nanowire is composed of a single constituent element, the gaseous precursor mixture is composed of the carrier gas and a single precursor that comprises the constituent element. For example, silane (SiH₄) can be used as the precursor for growing silicon nanowires. In an embodiment in which the semiconductor material of the nanowire is a compound semiconductor, i.e., a semiconductor composed of more than one constituent element, the gaseous precursor mixture is composed of the carrier gas and one or more precursors that collectively comprise the constituent elements of the compound semiconductor material. Typically, such gaseous precursor mixture has a different precursor for each constituent element of the compound semiconductor material. For example, precursors of trimethyl gallium (TMGa) and arsine (AsH₃) can be used as precursors for growing GaAs nanowires.

Referring now to FIG. 3D, molecules of the precursor in gaseous precursor mixture 266 that contact first nanoparticle 206 are catalytically decomposed by the material of the first nanoparticle and the adatoms of the constituent element resulting from the decomposition are deposited on the surface 207 of the first nanoparticle. The deposited adatoms mix with the original material of the nanoparticle to form an alloy. The alloy has a lower melting point than the original material of the nanoparticle.

FIG. 4 is a phase diagram showing how the melting point of an exemplary alloy formed when adatoms of silicon are deposited on the surface of a gold nanoparticle varies with the silicon fraction in the alloy. Temperature is plotted against the silicon fraction in the phase diagram. The phase diagram shows that, as the silicon fraction increases, the melting point of the alloy progressively decreases to about 380° C. at a silicon fraction of about 5%.

As a result of the fall in its melting point, first nanoparticle 206 melts to form a molten nanoparticle, as shown in FIG. 3D.

Referring now to FIG. 3E, additional adatoms of the constituent element deposited on surface 207 of molten first nanoparticle 206 increase the fraction of the constituent element in the alloy until the molten alloy becomes saturated with the constituent element. Then, further adatoms of the constituent element cause a corresponding number of atoms of the constituent element to be released from the molten nanoparticle at its surface adjacent substrate 200. The released atoms form a solid first nanowire 210 that extends between molten first nanoparticle 206 and substrate 200.

Further deposition of adatoms of the constituent element on the surface 207 of molten first nanoparticle 206 cause the release of additional atoms from the molten nanoparticle and an increase in the length of first nanowire 210, as shown in FIG. 3F. The process of passing gaseous precursor mixture 266 over substrate 200 is continued until first nanowire 210 reaches its desired length. Throughout the growth of first nanowire 210, first nanoparticle 206 remains at the distal end of the nanowire, remote from substrate 200.

First nanowire 210 has a lateral surface 211 that, during the growth of the nanowire, is also exposed to gaseous precursor mixture 266. Some of the molecules of the precursor contained in mixture 266 that contact lateral surface 211 decompose non-catalytically and deposit respective adatoms of the constituent element on the lateral surface. An exemplary adatom of the constituent element deposited on lateral surface 211 is shown at 213. Such adatoms typically accumulate on lateral surface 211 and impair the uniformity of the cross-sectional area of nanowire 210 along its length. The rate of lengthways growth of nanowire 210 is substantially constant, so the time that an annular segment of lateral surface 211 is exposed to gaseous precursor mixture 266 is inversely proportional to the distance of the annular segment from substrate surface 202. Consequently, adatoms 213 accumulated on lateral surface 211 typically cause nanowire 210 to be tapered in shape.

In embodiments in which non-tapered nanowires 210 are desired, a gaseous etchant, represented by arrows 268, may be included in the gaseous precursor mixture 266 as described in U.S. patent application Ser. No. 10/857,191, assigned to the assignee of this disclosure and incorporated by reference. Such gaseous etchant removes adatoms 213 of the constituent element of the semiconductor material of nanowire 210 from the lateral surface 211 of the nanowire. Since the adatoms of the constituent element are removed from lateral surface 211 as they are deposited during growth of nanowire 210 and before they incorporate into the lattice of the semiconductor material of the nanowire, nanowire 210 grows with a uniform cross-sectional area along its entire length, as shown in FIG. 3F.

Gaseous etchant 268 is an etchant that forms a volatile compound with adatoms 213 of the constituent element deposited on the lateral surface 211. The compound is volatile at the growth temperature and growth pressure established inside reactor 250. Molecules of the volatile compound are carried away from lateral surface 211 into the exhaust system 258 of reactor 250 by the gases passing over substrate 200. An exemplary molecule of the volatile compound formed between gaseous etchant 268 and an adatom released from gaseous precursor mixture 266 at lateral surface 211 is shown at 215. The etch rate of the adatoms deposited on lateral surface 211 is several orders of magnitude greater than that of the crystalline material of the lateral surface itself. As a result, the gaseous etchant removes the adatoms but has a negligible etching effect on lateral surface 211.

In an embodiment, gaseous etchant 268 was a halogenated hydrocarbon, such as halogenated methane. In one example, the halogenated methane was carbon tetrabromide (CBr₄). In another example, the halogenated methane was carbon tetrachloride (CCl₄). Not all the hydrogen atoms of the halogenated hydrocarbon or the halogenated methane need be substituted. Moreover, ones of the hydrogen atoms may be replaced by different halogens. In another embodiment, gaseous etchant 268 was a hydrogen halide (HX), where X=fluorine (F), chlorine (Cl), bromine (Br) or iodine (I).

An embodiment of substrate structure 230 in which the material of branched nanostructures 234 is silicon dioxide is made by performing an embodiment of method 100 in which the material of branched nanostructures 234 is silicon, as described above. Additional process 114 (FIG. 1) is then performed in which substrate structure 230 is subject to an oxygen plasma treatment to convert the silicon of the branched nanostructures to silicon dioxide. Other oxidation processes are known in the art and may alternatively be used.

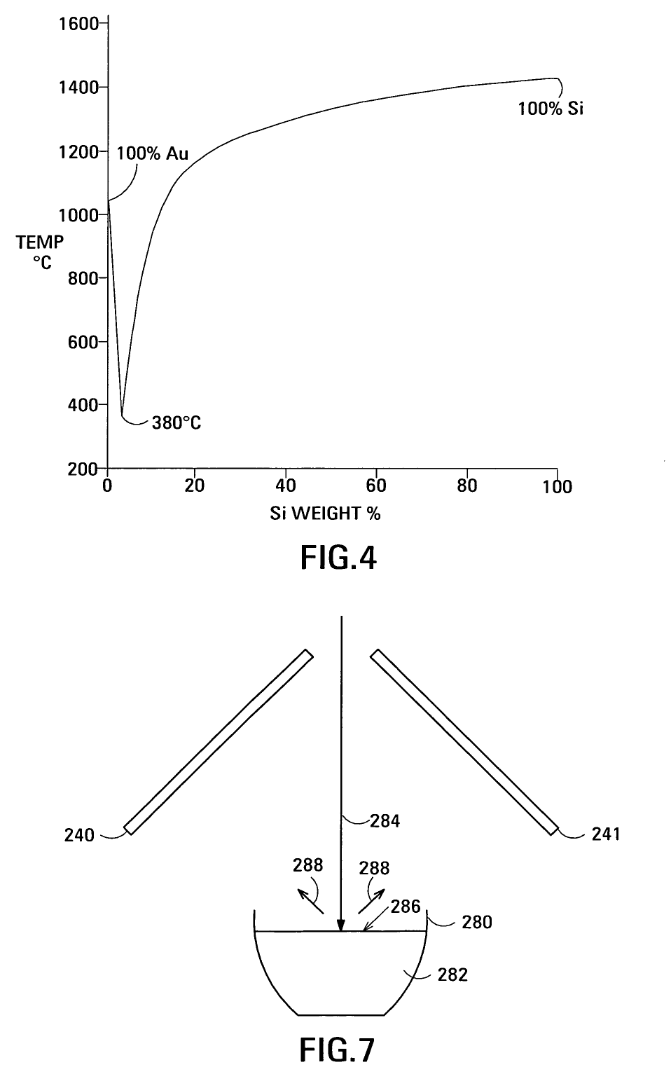

FIG. 5 is a flow chart illustrating a second embodiment 300 of a method in accordance with the invention for making a substrate structure with an enhanced surface area. In this embodiment, the material of the nanowires is oxidized prior to next nanoparticle deposition process. Oxidizing the nanowires allows the nanowires to be coated with polar molecules. The polar molecules increase the density with which the subsequently-deposited nanoparticles attach to the nanowires, and, hence, the density of the subsequently-grown nanowires. Elements of method 300 that correspond to elements of the method 100 described above with reference to FIG. 1 are indicated by the same reference numerals and will not be described again in detail.

In method 300, after silicon first nanowires 210 have been grown in block 106, as described above, and before second nanoparticles 212, 222 are deposited, block 320 is performed in which the first nanowires are oxidized. In block 320, the substrate structure composed of substrate 200 and first nanowires 210 is subject to an oxygen plasma treatment to convert the silicon of first nanowires 210 to silicon dioxide. Other oxidation processes are known in the art and may alternatively be used.

Then, block 308 is performed in which second nanoparticles 212, 222 are deposited. Block 308 is composed of blocks 322 and 324. In block 322, the nanowires are coated with polar molecules, which results in the nanowires acquiring a positive charge. In block 324, first nanowires 210 are exposed to second nanoparticles 212. The second nanoparticles, which are negatively charged, are attracted to the positive charge on the first nanowires and attach to the first nanowires. The density with which the second nanoparticles are deposited on the first nanowires is typically greater in this embodiment than in the embodiment described above with reference to FIG. 1 in which second nanoparticles 206 are deposited directly on the semiconductor material of first nanowires 210.

In an exemplary embodiment, the polar molecules were poly-l-lysine and were coated on the first nanowires 210 by dipping the wafer of which substrate 200 forms part into a 5-10% w/v aqueous solution of the poly-l-lysine. The wafer was then removed from the polar molecule solution, excess liquid was removed and the wafer was allowed to dry. The second nanoparticles 212, 222 were then deposited on the coated first nanowires by the process described above with reference to block 108 of FIG. 1.

Additionally, after second nanowires 214, 224 have been grown in block 110, as described above, block 326 is performed in which the second nanowires are oxidized. In block 326, the substrate structure comprising substrate 200, first nanowires 210 and second nanowires 214, 224 is subject to an oxygen plasma treatment to convert the silicon of second nanowires 214, 224 to silicon dioxide.

In an embodiment in which optional loop 112 is performed, the nanowires are coated with the polar molecules in block 322, additional nanoparticles are attached to the polar molecules in block 324, and additional nanowires are grown extending from the additional nanoparticles in block 110 as described above. The additional nanowires are then oxidized in block 326.

Optional block 116 may be performed as described above after block 326 has been performed a final time.

The material of the nanowires may be a semiconductor material different from silicon in other embodiments of method 300.

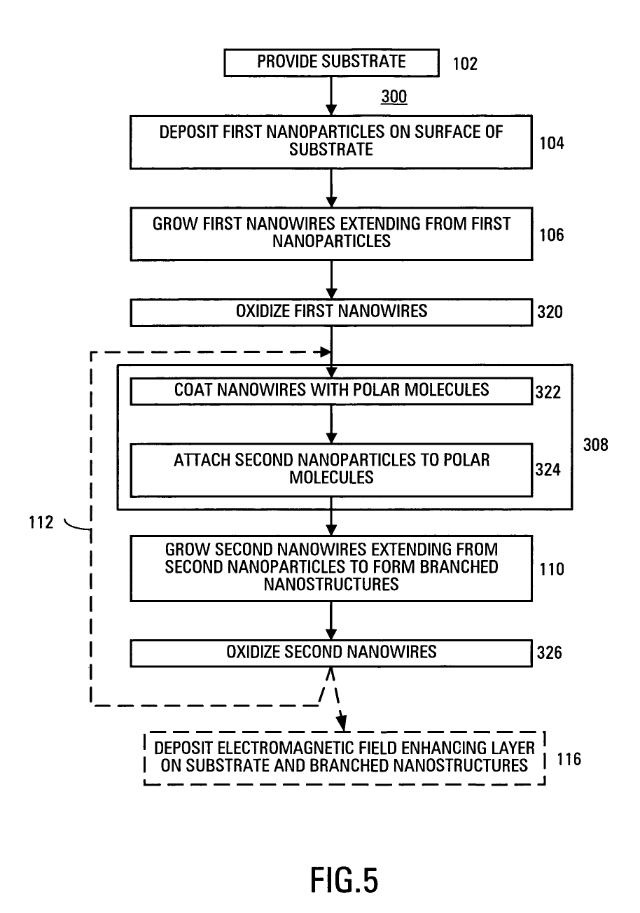

FIG. 6 is a flow chart illustrating a third embodiment 400 of a method in accordance with the invention for making a substrate structure having an enhanced surface area.

In block 402, a substrate is provided. In block 404, nanoparticles are deposited on the substrate surface. In block 406, nanowires are grown extending from the nanoparticles.

In block 408, a determination of whether the branched nanostructures formed by the growing process performed in block 406 have a predetermined level of branching. When the result is NO, blocks 404 and 406 are repeated. In repeating block 404, nanoparticles are additionally deposited on the nanowires, as represented by block 410. When the result is YES, the repetition of blocks 404 and 406 stops (block 412).

Method 400 may additionally include optional blocks 114 and 116 described above with reference to FIG. 1.

Alternatively, method 400 may include a nanowire oxidation block (not shown) following block 406. The nanowire oxidation block is similar to block 320 described above with reference to FIG. 5. In this case, block 410 comprises a polar molecule deposition block (not shown) and a nanoparticle attach block (not shown) similar to blocks 322 and 324 described above with reference to FIG. 5. Such embodiment may additionally comprise optional block 116.

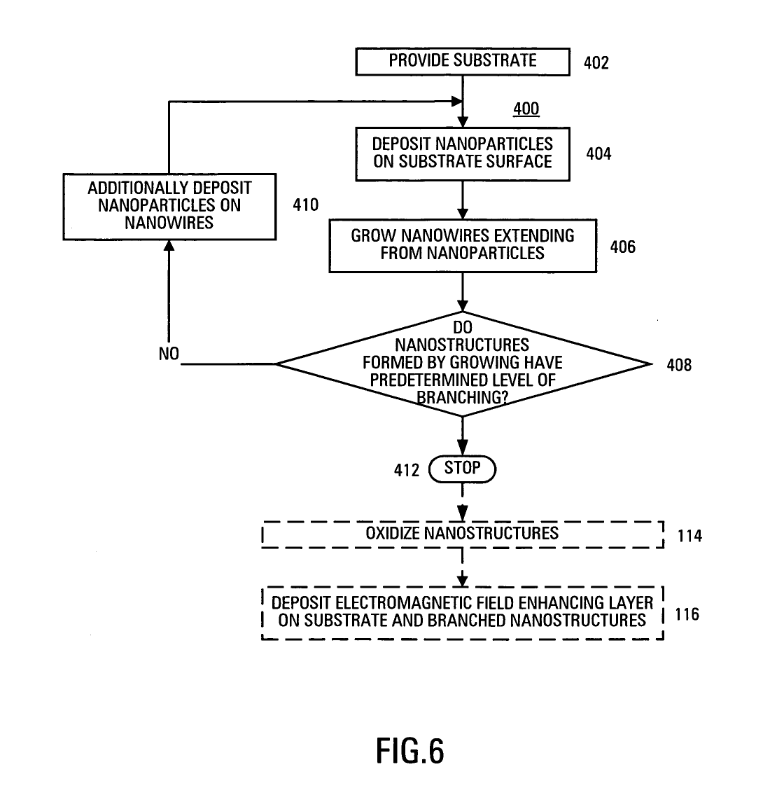

In the examples described above, nanoparticles 206, 212, 222, etc. are deposited by dipping substrate 200 in an aqueous colloidal solution of the nanoparticles. Alternatively, the nanoparticles may be deposited by e-beam evaporation. FIG. 7 shows a typical arrangement. In a vacuum chamber (not shown), wafers 240, 241 are arranged above a crucible 280 of nanoparticle material 282. Suitable nanoparticle materials include gold, silver and other materials as described above. Substrate 200 constitutes part of wafer 240, as described above. An electron beam 284 directed at the free surface 286 of nanoparticle material 282 evaporates small quantities of the nanoparticle material. The resulting nanoparticle material vapor, schematically indicated by arrows 288, condenses on the surface of wafers 240 and 242 as nanoparticles 206, 212, 222, etc.

This disclosure describes the invention in detail using illustrative embodiments. However, the invention defined by the appended claims is not limited to the precise embodiments described.

I claim:

1. A method of making a substrate structure, the method comprising:
providing a substrate having a surface;
depositing first nanoparticles on the surface of the substrate;
growing first nanowires extending from the first nanoparticles to the surface of the substrate;
depositing second nanoparticles on the first nanowires; and
growing second nanowires extending from the second nanoparticles to the first nanowires to form branched nanostructures.

2. The method of claim 1, additionally comprising oxidizing the first nanowires prior to depositing the second nanoparticles.

3. The method of claim 2, additionally comprising oxidizing the second nanowires.

4. The method of claim 3, additionally comprising depositing an electromagnetic field enhancing layer on the substrate and the branched nanostructures.

5. The method of claim 2, in which depositing the second nanoparticles comprises:
coating the first nanowires with polar molecules; and
attaching the second nanoparticles to the polar molecules.

6. The method of claim 5, in which the polar molecules comprise poly-L-lysine.

7. The method of claim 5, in which the first nanowires comprise an oxide of silicon.

8. The method of claim 5, additionally comprising depositing an electromagnetic field enhancing layer on the substrate and the branched nanostructures.

9. The method of claim 2, additionally comprising depositing an electromagnetic field enhancing layer on the substrate and the branched nanostructures.

10. The method of claim 1, additionally comprising:
depositing additional nanoparticles on the first nanowires and the second nanowires; and
growing additional nanowires from the additional nanoparticles.

11. The method of claim 10, in which:
the additional nanoparticles are smaller in average size than the second nanoparticles; and
the second nanoparticles are smaller in average size than the first nanoparticles.

12. The method of claim 10, additionally repeating depositing the additional nanoparticles and growing the additional nanowires.

13. The method of claim 10, additionally comprising depositing an electromagnetic field enhancing layer on the substrate and the branched nanostructures.

14. The method of claim 1, in which the second nanoparticles are smaller in average size than the first nanoparticles.

15. The method of claim 1, additionally comprising oxidizing the branched nanostructures.

16. A substrate structure, comprising:
a substrate having a substrate surface; and
branched nanostructures extending from the substrate surface, ones of the branched nanostructures having at least two levels of branching.

17. The substrate structure of claim 17, additionally comprising an electromagnetic field enhancing layer covering the branched nanostructures and the substrate surface.

18. The substrate structure of claim 17, in which the ones of the branched nanostructures comprise:
first nanowires extending from the substrate surface;
second nanowires extending from the first nanowires; and
additional nanowires extending from the second nanowires.

19. A method of making a substrate structure having an enhanced surface area, the method comprising:
providing a substrate having a substrate surface;
depositing nanoparticles on the substrate surface;
growing nanowires extending from the nanoparticles; and
repeating the depositing and the growing until branched nanostructures formed by the growing have a predetermined level of branching, the depositing comprising additionally depositing nanoparticles on the nanowires.

20. The method of claim 20, additionally comprising oxidizing the branched nanostructures.

21. The method of claim 20, additionally comprising depositing an electromagnetic field enhancing layer on the substrate and the branched nanostructures.
